(19) United States
(12) Patent Application Publication
(10) Pub. No.: US 2017/0062190 A1
(43) Pub. Date: Mar. 2, 2017

(54) PLASMA GENERATION APPARATUS

(71) Applicant: SAMSUNG ELECTRONICS CO., LTD., Suwon-si (KR)

(72) Inventors: Jae-hyun LEE, Yongin-si (KR); Jun-ho YOON, Suwon-si (KR); Jung-hyun CHO, Suwon-si (KR); Bok-yeon WON, Yongin-si (KR); Tae-hwa KIM, Hwaseong-si (KR)

(73) Assignee: SAMSUNG ELECTRONICS CO., LTD., Suwon-si (KR)

(21) Appl. No.: 15/132,506

(22) Filed: Apr. 19, 2016

(30) Foreign Application Priority Data
Aug. 26, 2015 (KR) 10-2015-0120546

(51) Int. Cl. H01J 37/32; H01L 21/67

(52) U.S. Cl. CPC H01J 37/32532; H01L 21/67069; H01J 37/32082; H01J 2237/334

(57) ABSTRACT

A plasma generation apparatus is provided. The plasma generation apparatus includes a chamber defining a reaction space that can be isolated from an external environment, an upper electrode provided in an upper portion of the chamber, a lower electrode provided in a lower portion of the chamber, a sidewall electrode provided at a sidewall of the chamber, a radio frequency (RF) pulse power supplier configured to supply RF pulse power to at least one selected from the upper electrode and the lower electrode, and a direct current (DC) pulse power supplier configured to supply DC pulse power to the sidewall electrode.

### CROSS-REFERENCE TO RELATED APPLICATION

This application claims priority from Korean Patent Application No. 10-2015-0120546, filed on Aug. 26, 2015 in the Korean Intellectual Property Office, the disclosure of which is incorporated herein in its entirety by reference.

### BACKGROUND

Apparatuses, methods and systems consistent with exemplary embodiments relate to plasma generation, and more particularly, to a plasma generation apparatus that is operated by a radio frequency (RF) pulse power supply.

When wafer processing such as etching and deposition of a wafer is performed using an RF pulse plasma generation apparatus, an electron temperature may be lowered more than a case where continuous wave (CW) plasma is used. Thus, the possibility of the wafer being damaged due to excessive decomposition of injected reactive gas may be reduced. However, a process error that may occur as electrons are concentrated in a specific area in a chamber.

### SUMMARY

One or more exemplary embodiments provide a plasma generation apparatus for improving process distribution.

According to an aspect of an exemplary embodiment, there is provided a plasma generation apparatus including: a chamber defining a reaction space that is isolated from an external environment; an upper electrode provided in an upper portion of the chamber; a lower electrode provided in a lower portion of the chamber; a sidewall electrode provided at a sidewall of the chamber; a radio frequency (RF) pulse power supplier configured to supply RF pulse power to at least one from among the upper electrode and the lower electrode; and a direct current (DC) pulse power supplier configured to supply DC pulse power to the sidewall electrode.

An on-time of the DC pulse power, during which the DC pulse power is supplied to the sidewall electrode, may be substantially equal to an off-time of the RF pulse power, during which the RF pulse power is not supplied to the upper electrode and the lower electrode.

A first section of an on-time of the DC pulse power, during which the DC pulse power is supplied to the sidewall electrode, may overlap with an off-time of the RF pulse power, during which the RF pulse power is not supplied to the upper electrode and the lower electrode, and a second section of the on-time of the DC pulse power other than the first section may overlap with a portion of an on-time of the RF pulse power, during which the RF pulse power is supplied to the at least one from among the upper electrode and the lower electrode.

A voltage value of the DC pulse power may be substantially constant during an on-time of the DC pulse power supplied by the DC pulse power supplier to the sidewall electrode.

A voltage value of the DC pulse power may vary during an on-time of the DC pulse power supplied by the DC pulse power supplier to the sidewall electrode.

The DC pulse power supplier may be further configured to, when electron density in a central area of the chamber is higher than an electron density in an outer area of the chamber surrounding the central area, supply the DC pulse power having a positive voltage value to the sidewall electrode.

The DC pulse power supplier may be further configured to, when electron density in a central area of the chamber is lower than an electron density in an outer area surrounding the central area, supply the DC pulse power having a negative voltage value to the sidewall electrode.

The plasma generation apparatus may further include a controller configured to supply a first pulse signal to the RF pulse power supplier to control supply of the RF pulse power by the RF pulse supplier and supply a second pulse signal synchronized with the first pulse signal to the DC pulse power supplier to control supply of the DC pulse power by the DC pulse power supplier.

The plasma generation apparatus may further include a monitoring unit configured to monitor a first electron density in a central region of the chamber and a second electron density in an outer area of the chamber surrounding the central region, and the controller may be further configured to adjust a voltage value of the DC pulse power based on the first electron density and the second electron density.

The plasma generation apparatus may further include a database configured to store a correlation model between the DC pulse power and an electron density in the chamber, and the controller may be further configured to adjust a voltage value of the DC pulse power based on the correlation model stored in the database.

According to an aspect of another exemplary embodiment, there is provided a plasma generation apparatus including: a chamber defining a reaction space that is isolated from an external environment; an upper electrode provided in an upper portion of the chamber; a lower electrode provided in a lower portion of the chamber; a sidewall electrode provided at a sidewall of the chamber; a first radio frequency (RF) pulse power supplier configured to supply first RF pulse power to the upper electrode; a second RF pulse power supplier configured to supply second RF pulse power to the lower electrode; and a direct current (DC) power supplier configured to supply DC power to the sidewall electrode during an off-time of the first RF pulse power and an off-time of the second RF pulse power.

There may be a phase difference between the first RF pulse power and the second RF pulse power, and the DC power supplier may be further configured to supply the DC power to the sidewall electrode when both the first RF pulse power and the second RF pulse power are pulsed off.

There may be a phase difference between the first pulse power and the second RF pulse power, and the DC power supplier may be further configured to supply the DC power during the off-time of the first RF pulse power or the off-time of the second RF pulse power.

The plasma generation apparatus may further include a controller configured to supply synchronized first and second pulse signals to the first and second RF pulse power suppliers, respectively.

The controller may be further configured the DC power so as to be synchronized with on-times and off-times of the first and second RF pulse powers.

According to an aspect of another exemplary embodiment, there is provided plasma generation apparatus including: a chamber defining a reaction space; a first electrode provided in an upper or lower portion the chamber; a second electrode provided at a sidewall of the chamber; a radio frequency (RF) pulse power supplier configured to supply RF pulse power to the first electrode, the RF pulse power having an on-time during which the RF power is pulsed on and an off-time during which the RF pulse power is pulsed off; and a direct current (DC) pulse power supplier configured to supply DC pulse power to the second electrode, the DC pulse power having an on-time during which the DC pulse power is pulsed on and an off-time during which the DC pulse power is pulsed off, wherein the on-time of the DC pulse power and the off-time of the RF pulse power overlap each other, and the off-time of the DC pulse power and the on-time of the RF pulse power overlap each other.

The on-time of the DC pulse power and the on-time of the RF pulse power may not overlap each other.

The on-time of the DC pulse power and the on-time of the RF pulse power may overlap each other.

The DC pulse power supplier may be further configured to, when an electron density in a central area of the chamber is higher than an electron density in an area surrounding the central area, supply the DC pulse power having a positive voltage during an on-time of the DC pulse power.

The DC pulse power supplier may be further configured to, when electron density in a central area of the chamber is lower than an electron density in an area surrounding the central area, supply the DC pulse power having a negative voltage during an on-time of the DC pulse power.

### BRIEF DESCRIPTION OF THE DRAWINGS

The above and/or other aspects will be more clearly understood from the following detailed description of exemplary embodiments taken in conjunction with the accompanying drawings in which:

FIG. 1 is a configuration diagram of a plasma generation apparatus according to an exemplary embodiment;

FIG. 2 is a timing diagram illustrating operations of an RF pulse power and a DC pulse power and electron density in a chamber which varies depending on the RF pulse power and the DC pulse power, according to an exemplary embodiment;

FIGS. 3A through 3D are timing diagrams illustrating operations of an RF pulse power and a DC pulse power, according to exemplary embodiments;

FIG. 4 is a configuration diagram of a plasma generation apparatus according to another exemplary embodiment;

FIG. 5 is a timing diagram illustrating operations of an RF pulse power and a DC pulse power and electron density in a chamber which varies depending on the RF pulse power and the DC pulse power, according to an exemplary embodiment;

FIG. 6 is a configuration diagram of a plasma generation apparatus according to another exemplary embodiment;

FIG. 7 is a configuration diagram of a plasma generation apparatus according to another exemplary embodiment;

FIG. 8 is a configuration diagram of a plasma generation apparatus according to another exemplary embodiment; and

FIGS. 9A and 9C are timing diagrams illustrating operations of first and second RF pulse powers and a DC pulse power, according to exemplary embodiments.

### DETAILED DESCRIPTION OF EXEMPLARY EMBODIMENTS

Exemplary embodiments will be described more fully with reference to the accompanying drawings. Like reference numerals refer to like elements throughout.

The inventive concept may, however, be embodied in many different forms and should not be construed as limited to the exemplary embodiments set forth herein. Rather, these embodiments are provided so that this disclosure will be thorough and complete, and will fully convey the scope to those skilled in the art. In the drawings, lengths and sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In a case where a certain embodiment may be implemented in a different way, a specific sequence of processes may be different from a sequence to be described. For example, two processes sequentially described may be simultaneously performed in reality, or may be performed in a sequence opposite to the sequence to be described.

As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing.

A plasma generation apparatus according to exemplary embodiments may use a capacitively coupled plasma (CCP) method in which wafers are arranged at a point having an RF voltage applied thereto, a magnetically-enhanced RIE (CCP-MERIE) method in which the possibility of ion generation is increased by applying a magnetic field to a plasma space to thereby perform etching, an electron cyclotron resonance (ECR) method in which resonance is generated by causing a microwave frequency to be incident thereon to thereby ionize neutral particles, a transformer coupled plasma (TCP) method in which an RF coil is used but the RF coil is only wound around an upper portion of a process chamber, an inductively coupled plasma (ICP) method in which an RF coil is used but the RF coil is wound around a side surface of a process chamber, a helical plasma method in which an RF coil is used in a spiral form, a high density plasma (HDP) method in which a portion generating plasma and a portion adjusting ion energy are independently controlled, or the like. However, the inventive concept is not limited thereto, and the plasma generation apparatus may use any method insofar as the plasma generation apparatus may apply RF power in the form of a pulse.

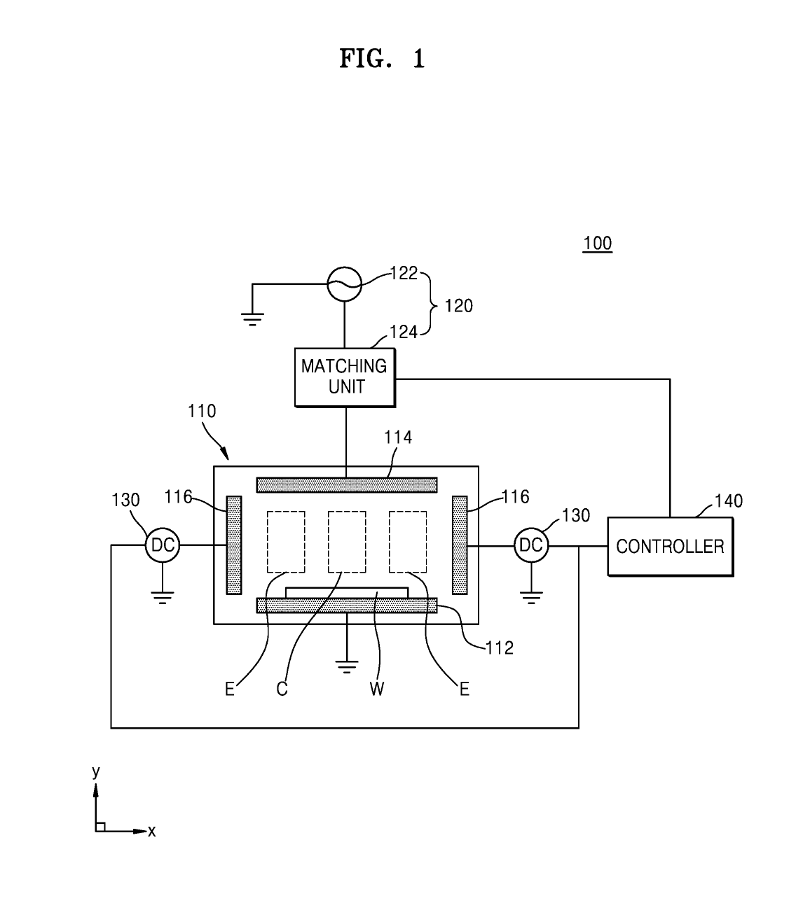

FIG. 1 is a configuration diagram of a plasma generation apparatus 100 according to an exemplary embodiment.

Referring to FIG. 1, the plasma generation apparatus 100 may include a chamber 110, an RF pulse power supplier 120, a DC pulse power supplier 130, and a controller 140.

The chamber 110 provides a plasma reaction space that is isolated from an external environment and may have various sizes and forms depending on a size of a wafer W on which a process is to be performed and on process characteristics.

In some exemplary embodiments, the chamber 110 may be formed of a metal, an insulator, or a combination thereof. In some exemplary embodiments, the inside of the chamber 110 may be coated with an insulator. The chamber 110 may have a rectangular parallelepiped shape or a cylindrical shape, but the inventive concept is not limited thereto.

A lower electrode 112 may be disposed in a lower portion of the chamber 110. The lower electrode 112 may function as a wafer chuck. In some exemplary embodiments, the lower electrode 112 may be an electrostatic chuck (ESC) that adsorbs and supports a wafer by an electrostatic force. Alternatively, in some exemplary embodiments, the lower electrode 112 may be a mechanical clamping type chuck or a vacuum chuck that adsorbs and supports a wafer by vacuum pressure. The lower electrode 112 may be provided with a heater that heats the wafer to a process temperature. In some exemplary embodiments, the lower electrode 112 may be grounded.

An upper electrode 114 may be disposed in an upper portion of the chamber 110. The pulse power supplier 120 that supplies an RF pulse power to the upper electrode 114 may be connected to the upper electrode 114 to generate plasma of a reaction gas.

In the current exemplary embodiment, although the RF pulse power supplier 120 is connected to the upper electrode 114 and the lower electrode 112 is grounded, the inventive concept is not limited thereto. For example, unlike the embodiment shown in FIG. 1, the upper electrode 114 may be grounded and the RF pulse power supplier 120 may be connected to the lower electrode 112.

As the RF pulse power supplier 120 supplies an RF pulse power to the upper electrode 114, a reaction gas diffused in the chamber 110 may be changed to a plasma state to react with the wafer W disposed on the lower electrode 112. In other words, the reaction gas is converted into plasma by the RF pulse power, which is applied to the upper electrode 114, as soon as the reaction gas is diffused in the chamber, and the plasma comes into contact with a surface of the wafer W and thus physically or chemically reacts with the wafer W. Wafer processing processes, such as plasma annealing, etching, plasma-enhanced chemical vapor deposition, physical vapor deposition, and plasma cleaning, may be performed through such reaction.

In some exemplary embodiments, the RF pulse power supplier 120 may include an RF power generator 122 and a matching unit 124. For example, the RF power generator 122 may generate a high frequency RF power. The matching unit 124 may output a pulse-modulated RF pulse power by mixing the RF power generated by the RF power generator 122 with a pulse signal output from the controller 140 as will be described below.

Accordingly, the RF pulse power supplier 120 may be operated in a pulse mode to supply pulse-modulated RF pulse power. In this manner, pulse plasma may be formed by pulsing RF power and applying the pulsed RF power to the upper electrode 114. In other words, plasma may be generated during an on-time of a pulse and may be extinguished during an off-time of the pulse. By using the pulse plasma for wafer processing, an electron temperature may be lowered as compared to using continuous wave (CW) plasma. Thus, the incidence of wafer damage occurring due to the excessive decomposition of an injected reactive gas may be lowered.

A plurality of sidewall electrodes 116 may be arranged at sidewalls of the chamber 110.

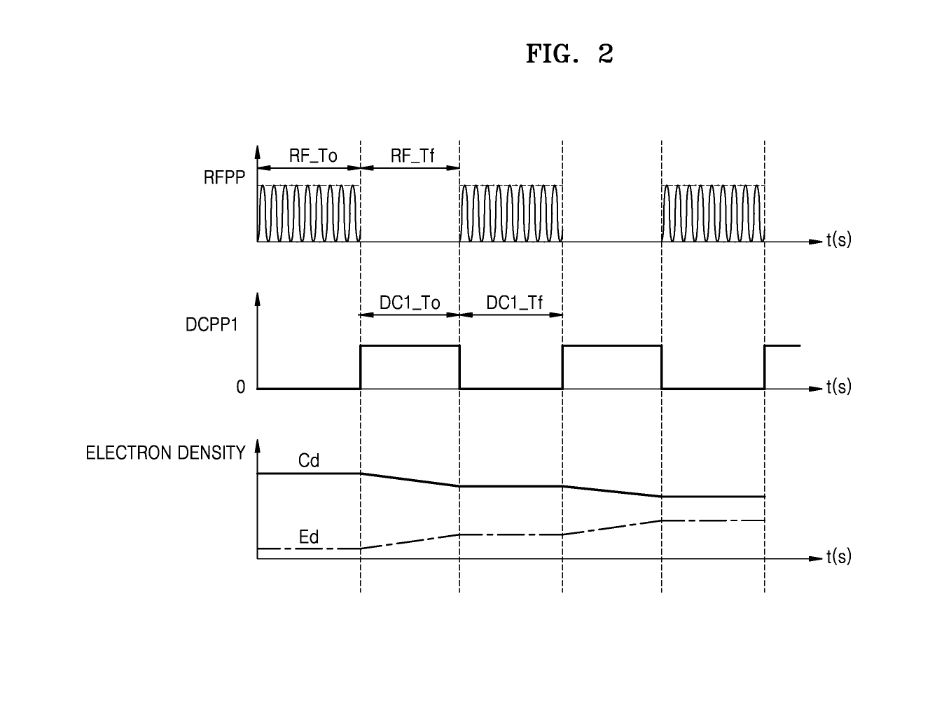

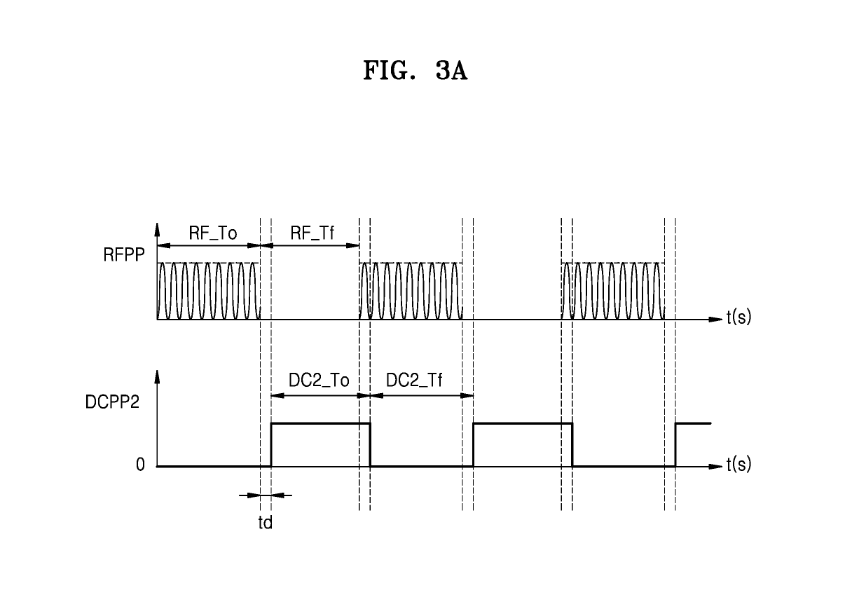

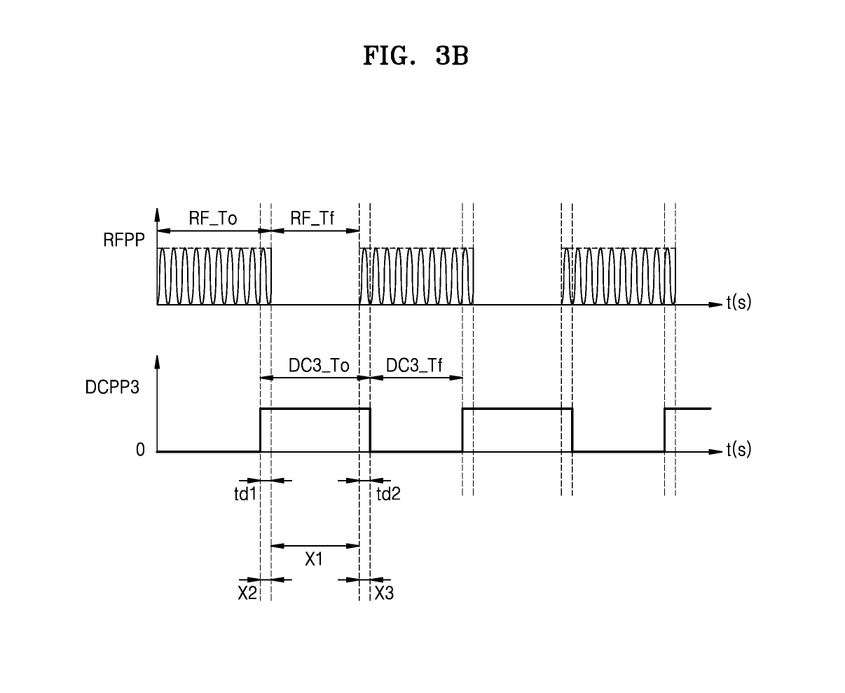

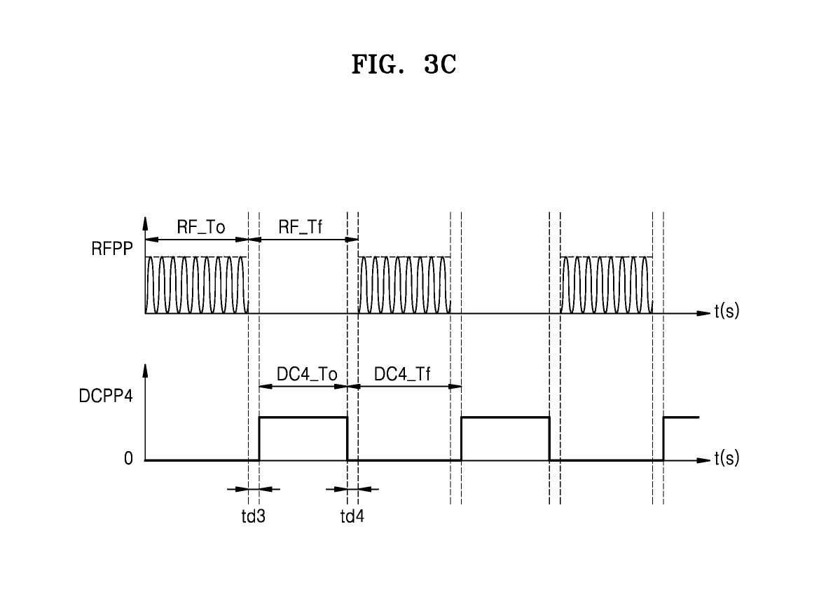

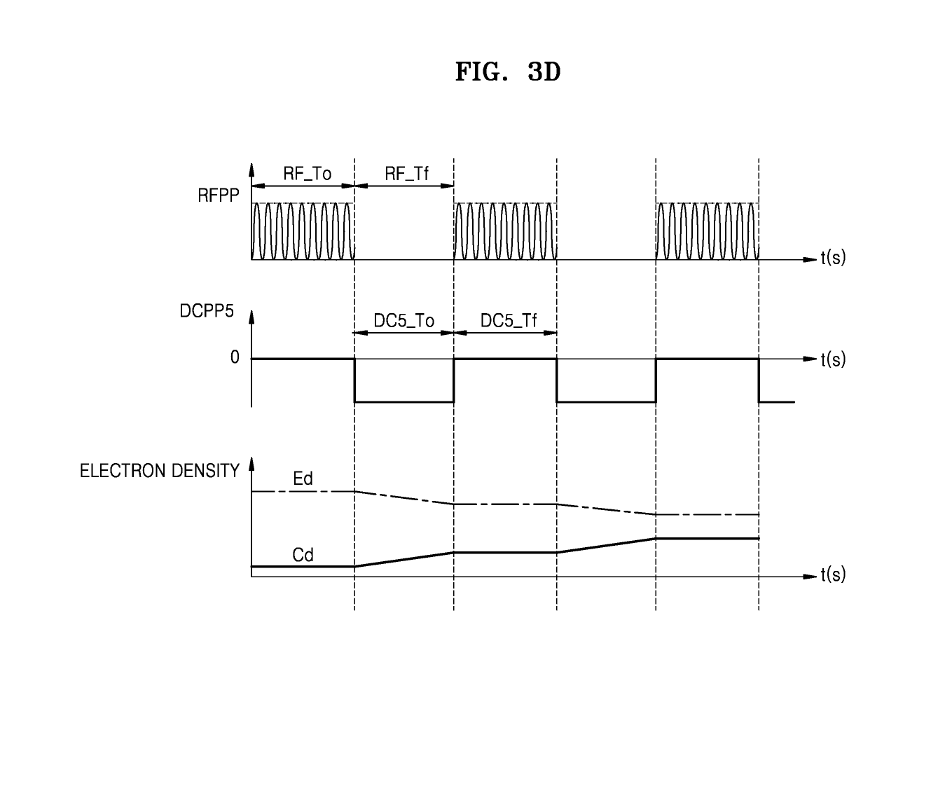

The DC pulse power supplier 130, which supplies a DC pulse power for adjusting the density of electrons or positive ions of etching gases in the chamber 110, may be connected to the sidewall electrodes 116. As the DC pulse power is supplied to the sidewall electrodes 116, electron density in a central area (C area) of the chamber 110 and electron density in an outside area (E area) surrounding the central area (C area) may be adjusted. This operation will be described in detail below with reference to FIGS. 2 and 3.

The controller 140 may be connected to the RF pulse power supplier 120 and the DC pulse power supplier 130 to control the RF pulse power supplier 120 and the DC pulse power supplier 130.

In some exemplary embodiments, the controller 140 may provide a first pulse signal to the RF pulse power supplier 120.

The matching unit 124 of the RF pulse power supplier 120 may mix an RF power, generated by the RF power generator 122, with the first pulse signal, output from the controller 140, and output a pulse-modulated RF pulse power. In other words, the controller 140 may control the matching unit 124 to turn-on or turn-off of the RF power so that the RF power is pulse-modulated.

In some exemplary embodiments, the controller 140 may provide a second pulse signal to the DC pulse power supplier 130. The second pulse signal may be synchronized with the first pulse signal. The DC pulse power supplier 130 may mix a DC power with the second pulse signal output from the controller 140 and output a DC pulse power.

In some other exemplary embodiments, the controller 140 may control the DC pulse power supplier 130 so that the DC pulse power supplier 130 outputs a DC pulse power, according to an on-time and an off-time of the first pulse signal. For example, the controller 140 may control the DC pulse power suppler 130 so that the DC pulse power suppler 130 supplies a DC power to the sidewall electrodes 116 only during the off-time of the first pulse signal.

FIG. 2 is a timing diagram illustrating operations of an RF pulse power and a DC pulse power and electron density in a chamber which varies depending on the RF pulse power and the DC pulse power, according to an exemplary embodiment.

Some elements of the plasma generation apparatus 100 shown in FIG. 1 may be referred to in descriptions related to FIG. 2.

Referring to FIG. 2, an RF pulse power RFPP may be supplied from the RF pulse power supplier 120 to the upper electrode 114.

The RF pulse power RFPP may denote that an RF power is supplied in a pulse mode. In other words, the RF power is supplied during on-time RF_To of the RF pulse power RFPP and is not supplied during off-time RF_Tf of the RF pulse power RFPP. Accordingly, plasma is generated during the on-time RF_To of the RF pulse power RFPP and is extinguished during the off-time RF_Tf of the RF pulse power RFPP.

During the on-time RF_To of the RF pulse power RFPP, a frequency of the RF pulse power RFPP may be about 13.56 MHz. However, the inventive concept is not limited thereto. For example, the frequency of the RF pulse power RFPP may be selected within a frequency range that is equal to or greater than about 1 MHz and is equal to or less than about 100 MHz.

A duty ratio of the RF pulse power RFPP may be, for example, 50% or more. The duty ratio may denote the ratio between the on-time RF_To and the off-time RF_Tf. For example, when the duty ratio is 60%, the on-time RF_To is 60% of the sum of the on-time RF_To and the off-time RF_Tf, and the off-time RF_Tf is 40% of the sum. When the duty ratio is 50%, the on-time RF_To is equal to the off-time RF_Tf. The duty ratio may be changed depending on a required wafer processing process, and the change of the duty ratio may have an influence on characteristics of pulse plasma to be generated.

A DC pulse power DCPP1 may be supplied from the DC pulse power supplier 130 to the sidewall electrodes 116.

The DC pulse power DCPP1 may be synchronized with the RF pulse power RFPP. For example, the DC pulse power DCPP1 may not be pulsing (hereinafter, referred to “pulsed off”) during the on-time RF_To of the RF pulse power RFPP and may be pulsing (hereinafter, referred to “pulsed on”) during the off-time RF_Tf of the RF pulse power RFPP. In other words, on-time DC1_To of the DC pulse power DCPP1 may be substantially equal to the off-time RF_Tf of the RF pulse power RFPP, and off-time DC1_Tf of the DC pulse power DCPP1 may be substantially equal to the on-time RF_To of the RF pulse power RFPP.

When the on-time RF_To of the RF pulse power RFPP is equal to the off-time RF_Tf of the RF pulse power RFPP, the duty ratio (DC1_To/(DC1_To+DC1_Tf) of the DC pulse power DCPP1 may be substantially equal to the duty ratio (RF_To/(RF_To+RF_Tf)) of the RF pulse power RFPP.

During the on-time RF_To of the RF pulse power RFPP, electrons existing in the chamber 110 may be trapped in plasma generated by the RF pulse power RFPP. However, during the off-time RF_Tf of the RF pulse power RFPP, the plasma may be extinguished and thus the electrons may freely move without being trapped. When a DC power is supplied to the sidewall electrodes 116 during the off-time RF_Tf of the RF pulse power RFPP, as in the current embodiment, the freely movable electrons may move in a direction (+X direction or −X direction of FIG. 1) parallel to the upper surface of the wafer W, depending on the DC power. Specifically, a positive (+) voltage may be applied to the sidewall electrodes 116 during the on-time DC1_To of the DC pulse power DCPP1, and thus, the electrons in the chamber 110 may be affected by an attractive force from the sidewall electrodes 116. Accordingly, as shown in FIG. 2, central electron density Cd in the central area (C area) of the chamber 110 decreases according to time, and outside electron density Ed in the outside area (E area) of the chamber 110 increases according to time.

When the DC pulse power DCPP1 having a positive (+) voltage is supplied to the sidewall electrodes 116 in this manner, a phenomenon in which the electrons in the chamber 110 are concentrated in the central area (C area) may be mitigated, and thus, a process distribution in a central area and an edge area of the wafer W may be improved.

FIGS. 3A through 3D are timing diagrams illustrating operations of an RF pulse power and a DC pulse power, according to exemplary embodiments.

Repeated descriptions reference labels in FIGS. 3A through 3D that are the same as those of FIG. 2 are omitted for simplification of description.

In addition, some elements of the plasma generation apparatus 100 shown in FIG. 1 may be referred to in descriptions related to FIGS. 3A through 3D.

Referring to FIG. 3A, an RF pulse power RFPP may be supplied from the RF pulse power supplier 120 to the upper electrode 114, and a DC pulse power DCPP2 may be supplied from the DC pulse power supplier 130 to the sidewall electrodes 116.

The DC pulse power DCPP2 may be supplied to the sidewall electrodes 116 while being synchronized with the RF pulse power RFPP and being shifted by a delay time td compared to the RF pulse power RFPP. In other words, the DC pulse power DCPP2 may not be pulsed on directly after the RF pulse power RFPP enters into the off-time RF_Tf from the on-time RF_To, but may be pulsed on after a lapse of the delay time td. In addition, the DC pulse power DCPP2 may not be pulsed off directly after the RF pulse power RFPP enters into the on-time RF_To from the off-time RF_Tf, but may be pulsed off after a lapse of the delay time td.

When the DC pulse power DCPP2 is supplied to the sidewall electrodes 116 while being shifted, a DC power may be supplied to be suitable for a pulse off-time even if the phase of the RF pulse power RFPP varies due to process variation.

Referring to FIG. 3B, an RF pulse power RFPP may be supplied from the RF pulse power supplier 120 to the upper electrode 114, and an DC pulse power DCPP3 may be supplied from the DC pulse power supplier 130 to the sidewall electrodes 116.

The DC pulse power DCPP3 may be supplied to the sidewall electrode 116 while being synchronized with the RF pulse power RFPP, and may be pulsed on in a portion of the on-time RF_To as well as the off-time RF_Tf of the RF pulse power RFPP. In other words, a first section X1 of on-time DC3_To of the DC pulse power DCPP3 may overlap with the off-time RF_Tf of the RF pulse power RFPP, and a remaining second section X2 and X3 other than the first section X1 in the on-time DC3_To of the DC pulse power DCPP3 may overlap with a portion of the on-time RF_To of the RF pulse power RFPP.

Specifically, the DC pulse power DCPP3 may be pulsed on for a delay time td1 before the RF pulse power RFPP enters into the off-time RF_Tf from the on-time RF_To, and may be pulsed off for a delay time td2 after the RF pulse power RFPP enters into the on-time RF_To from the off-time RF_Tf. In this case, the on-time DC3_To of the DC pulse power DCPP3 may be longer than the off-time RF_Tf of the RF pulse power RFPP.

When the on-time DC3_To of the DC pulse power DCPP3 overlaps with a portion of the on-time RF_To of the RF pulse power RFPP in this manner, a sufficient DC power may be supplied even while the RF pulse power RFPP may be distorted or offset due to a reflected wave.

Referring to FIG. 3C, an RF pulse power RFPP may be supplied from the RF pulse power supplier 120 to the upper electrode 114, and a DC pulse power DCPP4 may be supplied from the DC pulse power supplier 130 to the sidewall electrodes 116.

The DC pulse power DCPP4 may be supplied to the sidewall electrode 116 while being synchronized with the RF pulse power RFPP, and may be pulsed on only in a portion of the off-time RF_Tf of the RF pulse power RFPP. For example, the DC pulse power DCPP4 may be pulsed on for a delay time td3 after the RF pulse power RFPP enters into_the off-time RF_Tf from the on-time RF_To, and may be pulsed off for a delay time td4 before the RF pulse power RFPP enters into the on-time RF_To from the off-time RF_Tf.

When the DC pulse power DCPP4 is pulsed on only in a portion of the off-time RF_Tf of the RF pulse power RFPP, the DC pulse power DCPP4 may be supplied within a range that does not have an influence on a plasma processing process that may be performed during the on-time RF_To of the RF pulse power RFPP.

Referring to FIG. 3D, an RF pulse power RFPP may be supplied from the RF pulse power supplier 120 to the upper electrode 114, and an DC pulse power DCPP5 may be supplied from the DC pulse power supplier 130 to the sidewall electrodes 116.

When the DC pulse power DCPP5 is supplied to the sidewall electrode 116, as in the current embodiment, electrons, which may freely move during the off-time RF-Tf of the RF pulse power RFPP, may move in a direction (+X direction or −X direction of FIG. 1) parallel to the upper surface of the wafer W, depending to the DC pulse power DCPP5. Specifically, a negative (−) voltage may be applied to the sidewall electrodes 116 during the on-time DC5_To of the DC pulse power DCPP5, and thus, electrons in the chamber 110 may be affected by a repulsive force from the sidewall electrodes 116. Accordingly, as shown in FIG. 3D, central electron density Cd in the central area (C area) of the chamber 110 increases according to time, and outside electron density Ed in the outside area (E area) of the chamber 110 decreases according to time.

When the DC pulse power DCPP5 having a negative (−) voltage is supplied to the sidewall electrodes 116 in this manner, a phenomenon in which the electrons in the chamber 110 are concentrated in the outside area (E area) may be mitigated, and thus, a process distribution in a central area and an edge area of the wafer W may be improved.

In the current embodiment of FIG. 3D, although the DC pulse power DCPP5 is pulsed off during the on-time RF-To of the RF pulse power RFPP and is pulsed on during the off-time RF-Tf of the RF pulse power RFPP, the DC pulse power DCPP5 may be supplied to the sidewall electrodes 115 while being more shifted by a certain time than the RF pulse power RFPP, similar to the case described above with reference to FIG. 3A.

In some exemplary embodiments, the DC pulse power DCPP5 may be pulsed on in a portion of the on-time RF-To as well as the off-time RF-Tf of the RF pulse power RFPP, similar to the case described above with reference to FIG. 3B.

In some other exemplary embodiments, the DC pulse power DCPP5 may be pulsed on in a portion of the off-time RF-Tf of the RF pulse power RFPP, similar to the case described above with reference to FIG. 3C.

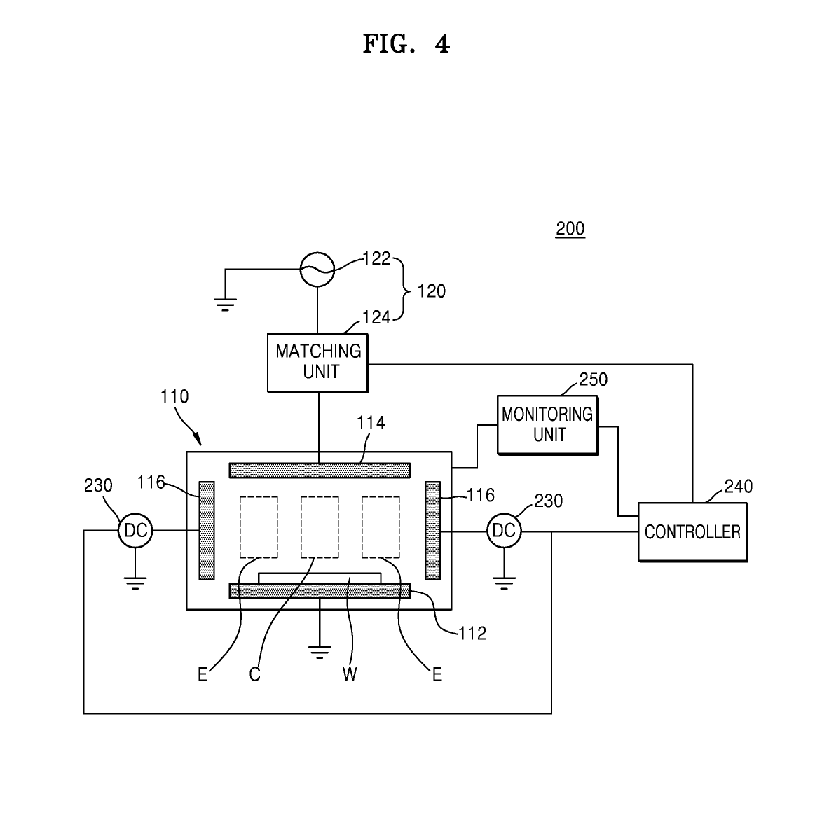

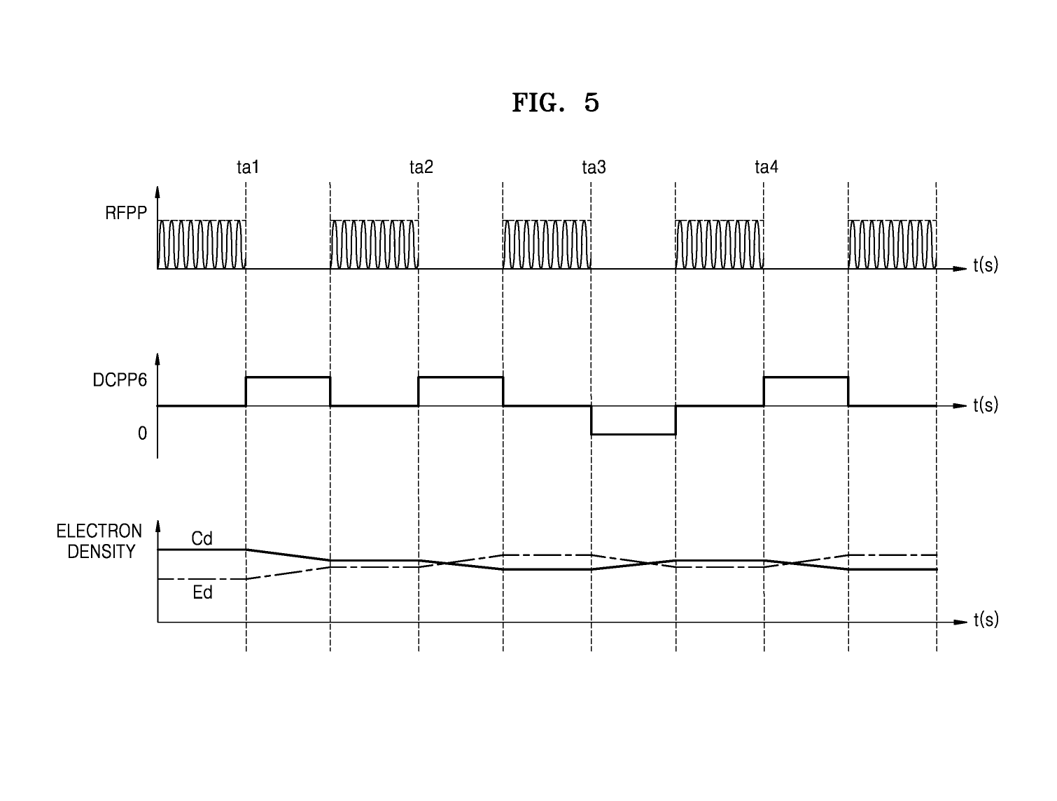

FIG. 4 is a configuration diagram of a plasma generation apparatus 200 according to another exemplary embodiment. FIG. 5 is a timing diagram illustrating an operation of an RF pulse power and an operation of a DC pulse power according to an exemplary embodiment and electron density in a chamber which varies depending on the RF pulse power and the DC pulse power.

Referring to FIGS. 4 and 5, the plasma generation apparatus 200 may include a chamber 110, an RF pulse power supplier 120, a DC pulse power supplier 230, a controller 240, and a monitoring unit 250.

The monitoring unit 250 may monitor the density of electrons existing in the chamber 110. For example, the monitoring unit 250 may monitor central electron density Dc in a central area (C area) of the chamber 110 and outside electron density Ed in an outside area (E area) of the chamber 110 in real time.

In some exemplary embodiments, the monitoring unit 250 may transmit data, which relates to the central electron density Cd and the outside electron density Ed, to the controller 240. The controller 240 may adjust a voltage value of a DC pulse power DCPP6 that is supplied to the sidewall electrodes 116 by the DC pulse power supplier 230, based on the central electron density Cd and the outside electron density Ed received from the monitoring unit 250.

Referring to the timing diagram shown in FIG. 5, if the central electron density Cd is higher than the outside electron density Ed at the moment (for example, at times ta1, ta2, and ta4) when the RF pulse power RFPP that is supplied by the RF pulse power supplier 120 enters into the off-time RF_Tf from the on-time RF_To (ta1, ta2, ta3, and ta4), the DC pulse power DCPP6 may supply a positive (+) voltage during a pulse on-time thereof. On the contrary, if the central electron density Cd is lower than the outside electron density Ed at the moment (for example, at times ta3) when the RF pulse power RFPP enters into the off-time RF_Tf from the on-time RF_To (ta1, ta2, ta3, and ta4), the DC pulse power DCPP6 may supply a negative (−) voltage during a pulse on-time thereof.

By monitoring the density of electrons existing in the chamber 110 and adjusting a voltage value of the DC pulse power DCPP6 based on the monitored density of electrons, a process distribution in a central area and an edge area of the wafer W may be improved.

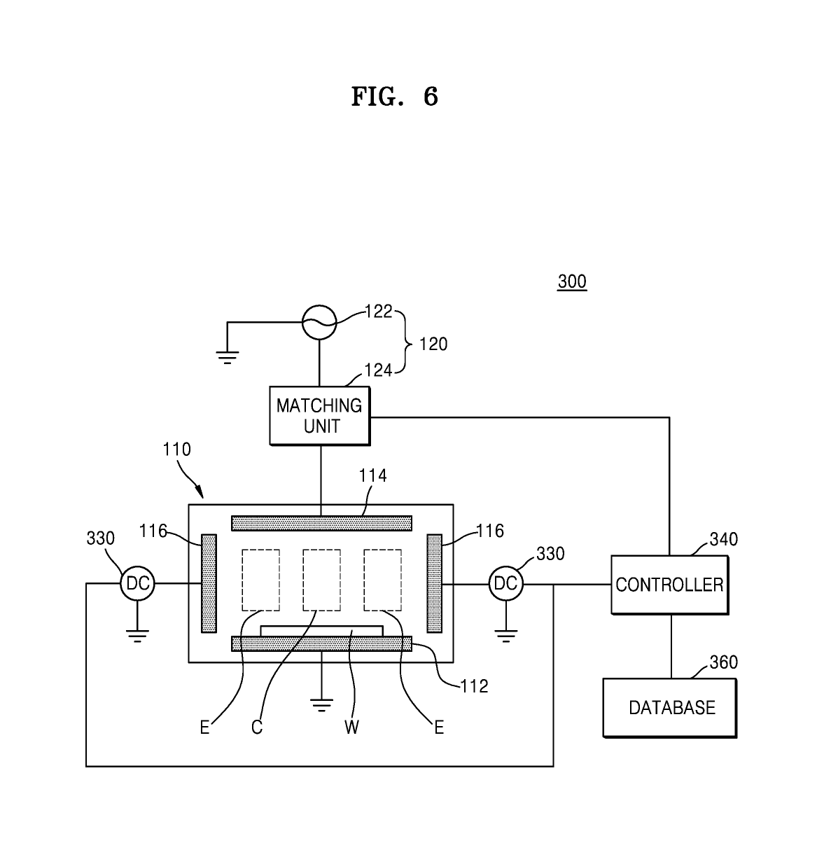

FIG. 6 is a configuration diagram of a plasma generation apparatus 300 according to another exemplary embodiment.

Referring to FIG. 6, the plasma generation apparatus 300 may include a chamber 110, an RF pulse power supplier 120, a DC pulse power supplier 330, a controller 340, and a memory storing a database 360.

A correlation model between a DC pulse power, which may be supplied by the DC pulse power supplier 330, and an electron density (for example, the central electron density Cd and the outside electron density Ed of FIG. 5) may be stored in the database 360, and the correlation model may be obtained through a test.

The correlation model between the DC pulse power and the electron density may include a correlation established by a non-modeling approach, such as a decision tree analysis algorithm, as well as a modeling approach such as a neural network algorithm.

In some exemplary embodiments, the correlation model between the DC pulse power and the electron density may be established through any of various algorithms, such as a multiple linear regression algorithm, a multiple nonlinear regression algorithm, a neural network algorithm, a support vector regression algorithm, a K nearest neighbor (KNN) regression algorithm, and a design of experiment (DOE) algorithm.

The database 360 may transmit the correlation model between the DC pulse power and the electron density to the controller 340. The controller 340 may control the DC pulse power, which is supplied to the sidewall electrode 116 by the DC pulse power supplier 330, based on the correlation model between the DC pulse power and the electron density.

By controlling the DC pulse power, which is supplied to the sidewall electrode 116 by the DC pulse power supplier 330, based on the correlation model between the DC pulse power and the electron density, the electron density in the central area (C area) and the electron density in the outside area (E area) may be controlled.

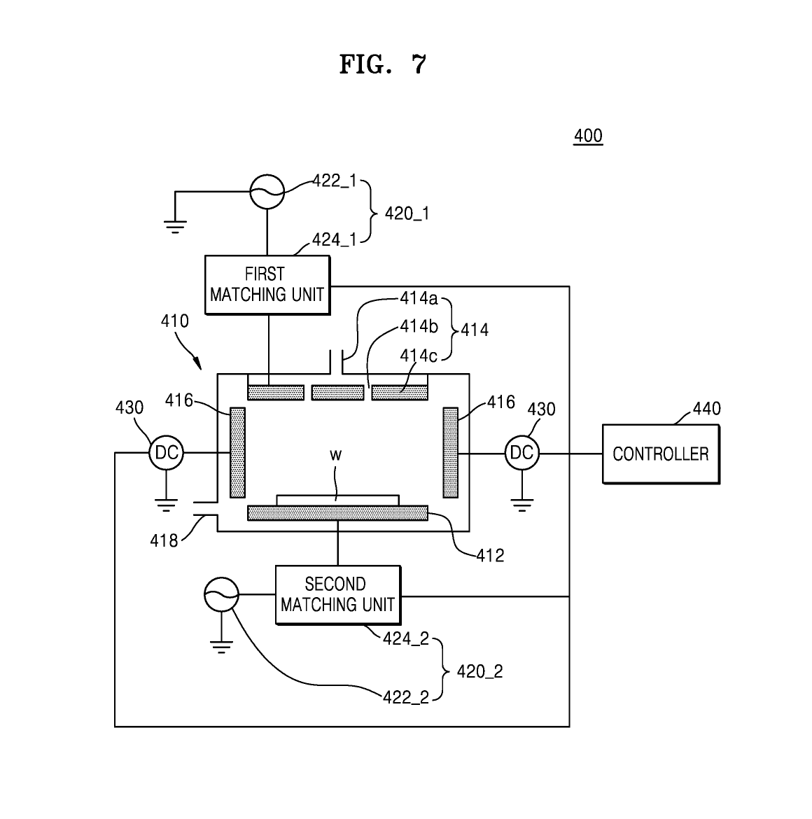

FIG. 7 is a configuration diagram of a plasma generation apparatus 400 according to another exemplary embodiment.

Referring to FIG. 7, the plasma generation apparatus 400 may include a chamber 410, first and second RF pulse power suppliers 420_1 and 420_2, a DC pulse power supplier 430, and a controller 440.

The chamber 410 may include a lower electrode 412, an upper electrode structure 414, a plurality of sidewall electrodes 416, and a gas-discharging unit 418.

The upper electrode structure 414 may include a gas-supplying unit 414a, a nozzle 414b, and an upper electrode 414c. In some embodiments, the gas-supplying unit 414a may be disposed in the upper electrode structure 414, as shown in FIG. 7. However, the inventive concept is not limited thereto. For example, the gas-supplying unit 414a may be disposed outside the chamber 410, independent of the upper electrode structure 414.

The gas-supplying unit 414a may supply a reaction gas to the chamber 410 via the nozzle 414b, and a gas may be exhausted via the gas-discharging unit 418 to maintain the chamber 410 in a vacuum state.

The first RF pulse power supplier 420_1 for applying a first RF pulse power to the upper electrode 414c may be connected to the upper electrode 414c.

In some embodiments, the first RF pulse power supplier 420_1 may include a first RF power generator 422_1 and a first matching unit 424_1.

In some exemplary embodiments, an RF power generated by the first RF power generator 422_1 and a pulse signal output from the controller 440 may be mixed in the first matching unit 424_1 to generate a pulse-modulated RF pulse power.

The first RF pulse power that is supplied by the first RF pulse power supplier 420_1 may be, for example, a source power.

In some exemplary embodiments, the first RF pulse power may be, for example, a high frequency (HF) pulse in a frequency range that is equal to or greater than about 13.56 MHz and is less than about 60 MHz or a very high frequency (VHF) pulse in a frequency range that is equal to or greater than about 60 MHz and is less that about several hundred MHz.

In some other embodiments, the first RF pulse power may be an RF pulse obtained by mixing multiple frequencies. For example, the first RF pulse power may be variously changed by mixing the VHF pulse and the HF pulse.

The lower electrode 412 may function as a wafer chuck. In some embodiments, the lower electrode 412 may be an ESC that adsorbs and supports a wafer by an electrostatic force. In some other embodiments, the lower electrode 412 may be a mechanical clamping type chuck or a vacuum chuck that adsorbs and supports a wafer by vacuum pressure.

In some exemplary embodiments, a second RF pulse power supplier 420_2 may be connected to the lower electrode 412. The second RF pulse power supplier 420_2 may include a second RF power generator 422_2 and a second matching unit 424_2.

In some exemplary embodiments, an RF power generated by the second RF power generator 422_2 and a pulse signal output from the controller 440 may be mixed in the second matching unit 424_2 to generate a pulse-modulated RF pulse power.

The second RF pulse power that is supplied by the second RF pulse power supplier 420_1 may be a bias power.

The second RF pulse power supplier 420_2 may supply the second RF pulse power in a frequency that is lower than that of the first RF pulse power that is supplied by the first RF pulse power supplier 420_1. For example, the second RF pulse power may be a low frequency (LF) pulse in a frequency range that is equal to or greater than about 0.1 MHz and is less than about 13.56 MHz.

The plasma generation apparatus 400 may use a CCP method. Specifically, when the first RF pulse power is supplied to the upper electrode 414c and the second RF pulse power is supplied to the lower electrode 412, an electric field may be induced between the upper electrode 414c and the lower electrode 412. At this time, when a reaction gas is injected in the chamber 410 via the gas-supplying unit 414a installed in the top of the chamber 410, the reaction gas may be changed to a plasma state due to an electric field induced inside the chamber 410. A wafer processing process, such as an etching or thin film deposition process for a wafer W, may be performed by using the generated plasma.

In some exemplary embodiments, the first RF pulse power that is supplied to the upper electrode 414c may perform a function of igniting plasma, and the second RF pulse power that is supplied to the lower electrode 412 may perform a function of controlling plasma.

The plurality of sidewall electrodes 416 may be arranged at sidewalls of the chamber 410. The DC pulse power supplier 430, which supplies a DC pulse power for adjusting the density of electrons or positive ions of etching gases in the chamber 410, may be connected to the sidewall electrodes 416.

The controller 440 may control the first and second RF pulse power suppliers 420_1 and 420_2 and the DC pulse power supplier 430.

In some exemplary embodiments, RF powers generated by the first and second RF power generators 422_1 and 422_2 and a DC power generated in the DC pulse power supplier 430 may be pulse-modulated by the control of the controller 440. In addition, first and second RF pulse powers that are supplied by the first and second RF pulse power suppliers 420_1 and 420_2 and a DC pulse power that is supplied by the DC pulse power supplier 430 may be synchronized by the control of the controller 440.

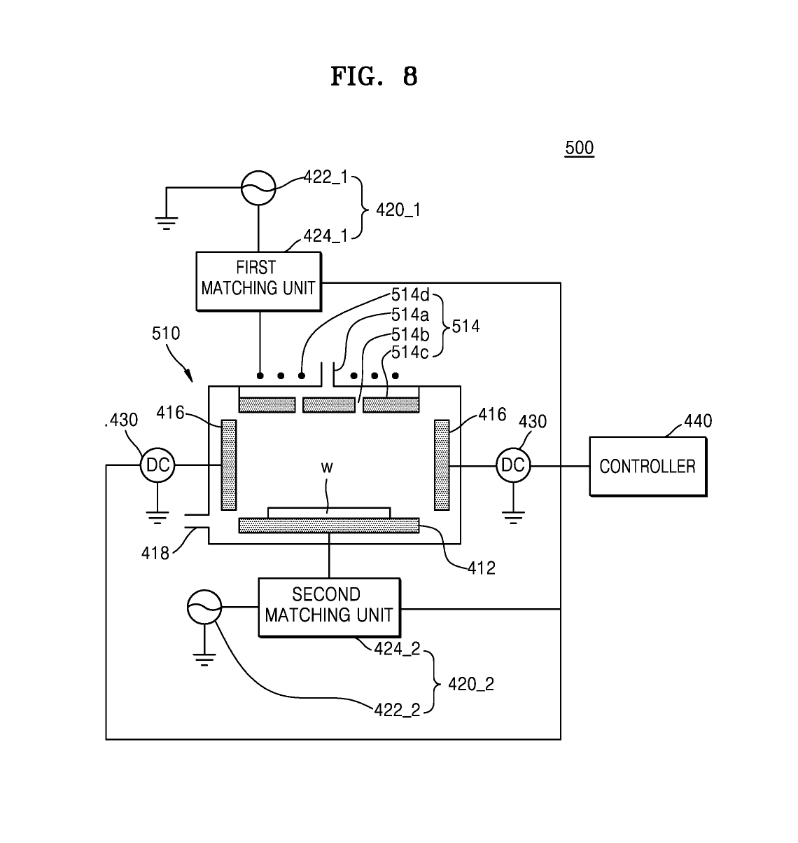

FIG. 8 is a configuration diagram of a plasma generation apparatus 500 according to another exemplary embodiment.

Referring to FIG. 8, the plasma generation apparatus 500 may include a chamber 510, first and second RF pulse power suppliers 420_1 and 420_2, a DC pulse power supplier 430, and a controller 440.

The chamber 510 may include a lower electrode 412, an upper electrode structure 514, a plurality of sidewall electrodes 416, and a gas-discharging unit 418.

The upper electrode structure 514 may include a gas-supplying unit 514a, a nozzle 514b, an insulating plate 514c, and an antenna 514d. In some embodiments, the gas-supplying unit 514a may be disposed in the upper electrode structure 514, as shown in FIG. 8. However, the inventive concept is not limited thereto. For example, the gas-supplying unit 514a may be disposed outside the chamber 510, independent of the upper electrode structure 514.

The gas-supplying unit 514a may supply a reaction gas to the chamber 510 via the nozzle 514b, and a gas may be exhausted via the gas-discharging unit 518 to maintain the chamber 510 in a vacuum state.

The plasma generation apparatus 500 may use an ICP method. Specifically, after the chamber 510 is exhausted by the gas-discharging unit 518, a reaction gas for generating plasma is supplied from the gas-supplying unit 514a to the chamber 510. Furthermore, a first RF pulse power from the first RF pulse power supplier 420_1 is applied to the antenna 514a. As the first RP pulse power is applied to the antenna 514d, lines of magnetic force may be formed around the antenna 514d. An induced electric field may be formed inside the chamber 510 due to the lines of magnetic force, and the induced electric field may heat electrons to generate ICP.

In some exemplary embodiments, the insulating plate 514c may be disposed between the antenna 514d and the lower electrode 412. The insulating plate 514c may facilitate transmission of energy supplied from the first RF pulse power supplier 420_1 to plasma by an inductive coupling by reducing a capacitive coupling between the antenna 514d and the plasma.

The antenna 514d may have one or more spiral coil shapes as seen in a plan view. However, the inventive concept is not limited thereto. For example, the antenna 514d may have various shapes other than the spiral coil shape.

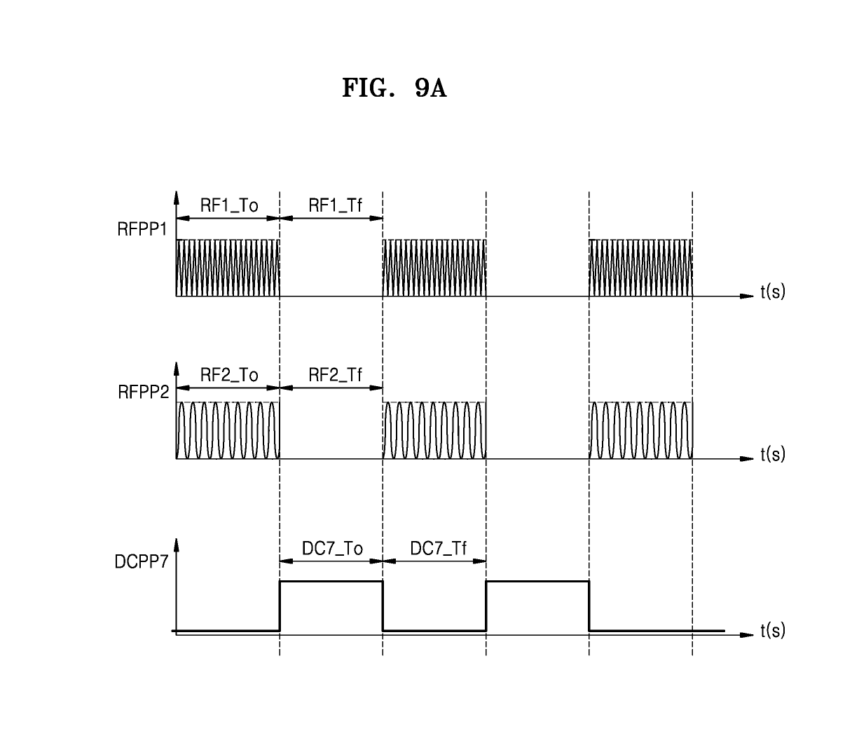

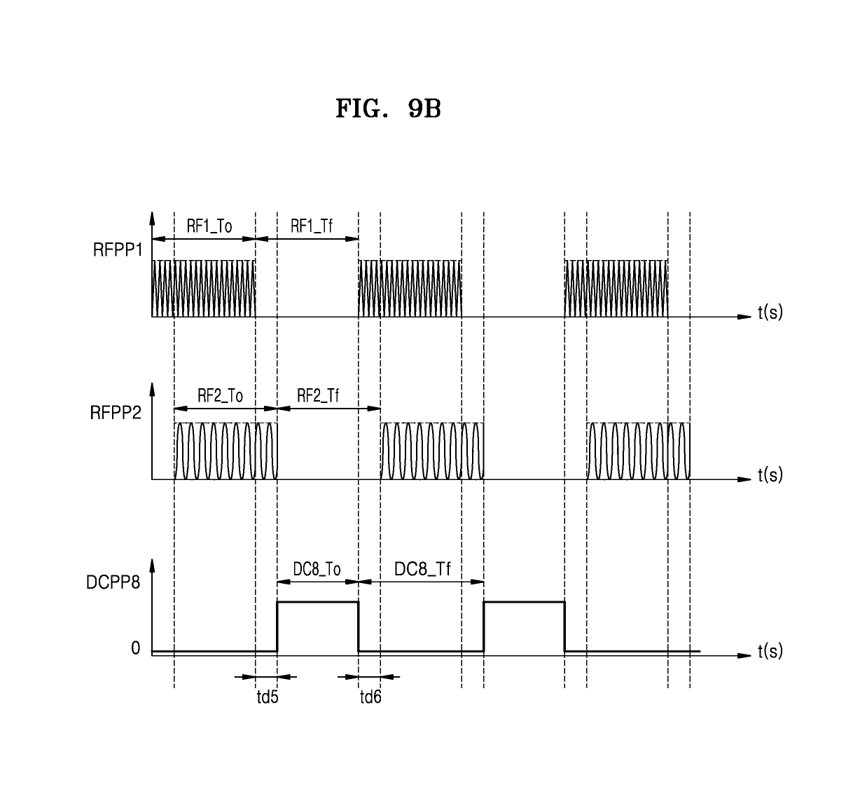

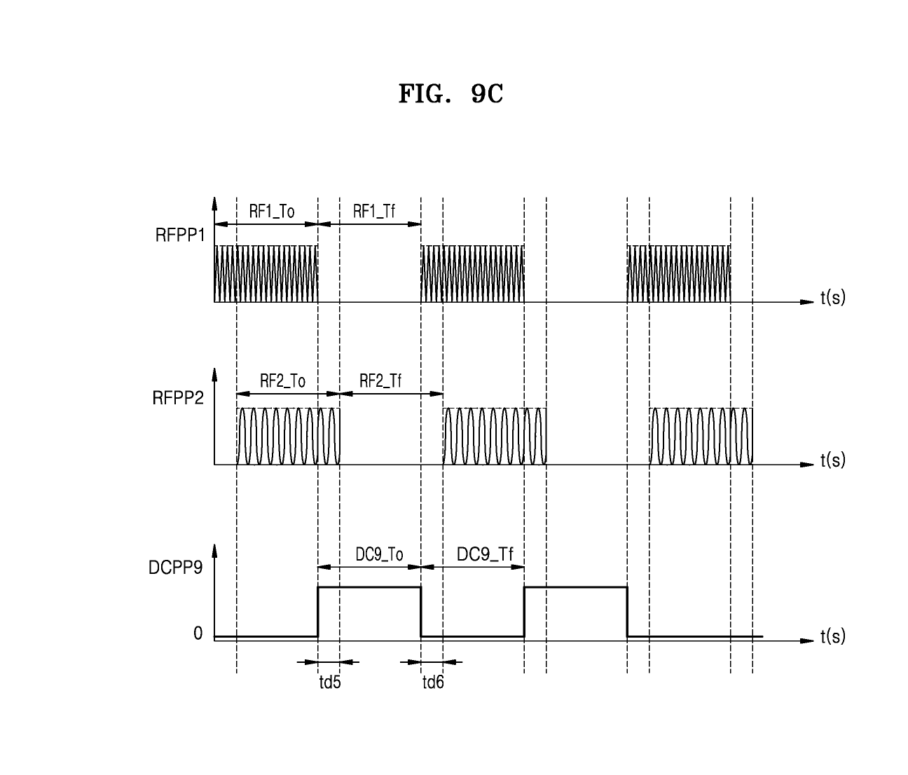

FIGS. 9A through 9C are timing diagrams illustrating operations of first and second RF pulse powers and an operation of a DC pulse power according to exemplary embodiments.

Some elements of the plasma generation apparatus 400 shown in FIG. 7 may be referred to in descriptions referred to FIGS. 9A through 9C.

Referring to FIG. 9A, a first RF pulse power RFPP1 may be supplied from the first RF pulse power supplier 420_1 to the upper electrode 414c, a second RF pulse power RFPP2 may be supplied from the second RF pulse power supplier 420_2 to the lower electrode 412, and a DC pulse power DCPP7 may be supplied from the DC pulse power supplier 430 to the sidewall electrodes 416.

The first RF pulse power RFPP1 and the second RF pulse power RFPP2 may be synchronized with each other. In some embodiments, the first RF pulse power RFPP1 and the second RF pulse power RFPP2 may be simultaneously pulsed on and pulsed off without having a phase difference. Accordingly, the on-time RF1_To and the off-time RF1_Tf of the first RF pulse power RFPP1 may be substantially the same as the on-time RF2_To and the off-time RF2_Tf of the second RF pulse power RFPP2, respectively.

The DC pulse power DCPP7 may be synchronous with the first RF pulse power RFPP1 and the second RF pulse power RFPP2.

For example, as shown in FIG. 9A, the DC pulse power DCPP1 may be pulsed off during the on-times RF1_To and RF2_To of the first and second RF pulse powers RFPP1 and RFPP2, and may be pulsed on during the off-times RF1_Tf and RF2_Tf of the first and second RF pulse powers RFPP1 and RFPP2. In other words, the on-time DC7_To of the DC pulse power DCPP7 may be substantially the same as the off-times RF1_Tf and RF2_Tf of the first and second RF pulse powers RFPP1 and RFPP2, and the off-time DC7_Tf of the DC pulse power DCPP7 may be substantially the same as the on-times RF1_To and RF2_To of the first and second RF pulse powers RFPP1 and RFPP2.

Referring to FIG. 9B, a first RF pulse power RFPP1 may be supplied from the first RF pulse power supplier 420_1 to the upper electrode 414c, a second RF pulse power RFPP2 may be supplied form the second RF pulse power supplier 420_2 to the lower electrode 412, and a DC pulse power DCPP8 may be supplied from the DC pulse power supplier 430 to the sidewall electrodes 416.

The first RF pulse power RFPP1 and the second RF pulse power RFPP2 may be synchronized with each other, but may be supplied with having a phase difference. In other words, the second RF pulse power RFPP2 may be shifted by a delay time td5 compared to the first RF pulse power RFPP1. Specifically, the second RF pulse power RFPP2 may not be pulsed off directly after the first RF pulse power RFPP1 enters into the off-time RF_Tf from the on-time RF_To, but may be pulsed off after a lapse of a delay time td5. In addition, the second RF pulse power RFPP2 may not be pulsed on directly after the first RF pulse power RFPP1 enters into the on-time RF_To from the off-time RF_Tf, but may be pulsed on after a lapse of a delay time td6.

In some embodiments, as shown in FIG. 9B, the DC pulse power DCPP8 may be pulsed on when both the first RF pulse powers RFPP1 and the second RF pulse power RFPP2 are pulsed off, that is, only in a period in which the off-time RF1_Tf of the first RF pulse powers RFPP1 and the off-time RF2_Tf of the second RF pulse power RFPP2 overlap each other.

In this case, the on-time DC8_To of the DC pulse power DCPP8 may be shorter than the off-time RF1_f of the first RF pulse power RFPP1 or the off-time RF2_Tf of the second RF pulses power RFPP2, and the off-time DC8_Tf of the DC pulse power DCPP8 may be longer than the on-time RF1_To of the first RF pulse power RFPP1 or the on-time RF2_To of the second RF pulses power RFPP2.

Referring to FIG. 9C, a first RF pulse power RFPP1 may be supplied from the first RF pulse power supplier 420_1 to the upper electrode 414c, a second RF pulse power RFPP2 may be supplied form the second RF pulse power supplier 420_2 to the lower electrode 412, and a DC pulse power DCPP9 may be supplied from the DC pulse power supplier 430 to the sidewall electrodes 416.

As described with reference with FIG. 9B, the second RF pulse power RFPP2 may be shifted by a delay time td5 compared to the first RF pulse power RFPP1.

In some embodiments, the DC pulse power DCPP9 may be pulsed on during the off-time of one selected from the first and second RF pulse powers RFPP1 and RFPP2. For example, the DC pulse power DCPP9 may be pulsed on during the off-time RF1_Tf of the first RF pulse power RFPP1.

In this case, the on-time DC9_To of the DC pulse power DCPP9 may be substantially equal to the off-time RF1_Tf of the first RF pulse power RFPP1, and the off-time DC9_Tf of the DC pulse power DCPP9 may be substantially equal to the on-time RF1_To of the first RF pulse power RFPP1.

While the inventive concept has been particularly shown and described with reference to exemplary embodiments thereof, it will be understood that various changes in form and details may be made therein without departing from the spirit and scope of the following claims.

What is claimed is:

1. A plasma generation apparatus comprising:
a chamber defining a reaction space that is isolated from an external environment;
an upper electrode provided in an upper portion of the chamber;
a lower electrode provided in a lower portion of the chamber;
a sidewall electrode provided at a sidewall of the chamber;
a radio frequency (RF) pulse power supplier configured to supply RF pulse power to at least one from among the upper electrode and the lower electrode; and
a direct current (DC) pulse power supplier configured to supply DC pulse power to the sidewall electrode.

2. The plasma generation apparatus of claim 1, wherein an on-time of the DC pulse power, during which the DC pulse power is supplied to the sidewall electrode, is substantially equal to an off-time of the RF pulse power, during which the RF pulse power is not supplied to the upper electrode and the lower electrode.

3. The plasma generation apparatus of claim 1, wherein a first section of an on-time of the DC pulse power, during which the DC pulse power is supplied to the sidewall electrode, overlaps with an off-time of the RF pulse power, during which the RF pulse power is not supplied to the upper electrode and the lower electrode, and a second section of the on-time of the DC pulse power other than the first section overlaps with a portion of an on-time of the RF pulse power, during which the RF pulse power is supplied to the at least one from among the upper electrode and the lower electrode.

4. The plasma generation apparatus of claim 1, wherein a voltage value of the DC pulse power is substantially constant during an on-time of the DC pulse power supplied by the DC pulse power supplier to the sidewall electrode.

5. The plasma generation apparatus of claim 1, wherein a voltage value of the DC pulse power varies during an on-time of the DC pulse power supplied by the DC pulse power supplier to the sidewall electrode.

6. The plasma generation apparatus of claim 1, wherein the DC pulse power supplier is further configured to, when electron density in a central area of the chamber is higher than an electron density in an outer area of the chamber surrounding the central area, supply the DC pulse power having a positive voltage value to the sidewall electrode.

7. The plasma generation apparatus of claim 1, wherein the DC pulse power supplier is further configured to, when electron density in a central area of the chamber is lower than an electron density in an outer area surrounding the central area, supply the DC pulse power having a negative voltage value to the sidewall electrode.

8. The plasma generation apparatus of claim 1, further comprising a controller configured to supply a first pulse signal to the RF pulse power supplier to control supply of the RF pulse power by the RF pulse supplier and supply a second pulse signal synchronized with the first pulse signal to the DC pulse power supplier to control supply of the DC pulse power by the DC pulse power supplier.

9. The plasma generation apparatus of claim 8, further comprising a monitoring unit configured to monitor a first electron density in a central region of the chamber and a second electron density in an outer area of the chamber surrounding the central region,
wherein the controller is further configured to adjust a voltage value of the DC pulse power based on the first electron density and the second electron density.

10. The plasma generation apparatus of claim 8, further comprising a database configured to store a correlation model between the DC pulse power and an electron density in the chamber,
wherein the controller is further configured to adjust a voltage value of the DC pulse power based on the correlation model stored in the database.

11. A plasma generation apparatus comprising:
a chamber defining a reaction space that is isolated from an external environment;
an upper electrode provided in an upper portion of the chamber;
a lower electrode provided in a lower portion of the chamber;
a sidewall electrode provided at a sidewall of the chamber;
a first radio frequency (RF) pulse power supplier configured to supply first RF pulse power to the upper electrode;
a second RF pulse power supplier configured to supply second RF pulse power to the lower electrode; and
a direct current (DC) power supplier configured to supply DC power to the sidewall electrode during an off-time of the first RF pulse power and an off-time of the second RF pulse power.

12. The plasma generation apparatus of claim 11, wherein there is a phase difference between the first RF pulse power and the second RF pulse power, and the DC power supplier is further configured to supply the DC power to the sidewall electrode when both the first RF pulse power and the second RF pulse power are pulsed off.

13. The plasma generation apparatus of claim 11, wherein there is a phase difference between the first pulse power and the second RF pulse power, and the DC power supplier is further configured to supply the DC power during the off-time of the first RF pulse power or the off-time of the second RF pulse power.

14. The plasma generation apparatus of claim 11, further comprising a controller configured to supply synchronized first and second pulse signals to the first and second RF pulse power suppliers, respectively.

15. The plasma generation apparatus of claim 14, wherein the controller is further configured the DC power so as to be synchronized with on-times and off-times of the first and second RF pulse powers.

16. A plasma generation apparatus comprising:
a chamber defining a reaction space;
a first electrode provided in an upper or lower portion the chamber;
a second electrode provided at a sidewall of the chamber;
a radio frequency (RF) pulse power supplier configured to supply RF pulse power to the first electrode, the RF pulse power having an on-time during which the RF power is pulsed on and an off-time during which the RF pulse power is pulsed off; and
a direct current (DC) pulse power supplier configured to supply DC pulse power to the second electrode, the DC pulse power having an on-time during which the DC pulse power is pulsed on and an off-time during which the DC pulse power is pulsed off,
wherein the on-time of the DC pulse power and the off-time of the RF pulse power overlap each other, and the off-time of the DC pulse power and the on-time of the RF pulse power overlap each other.

17. The plasma generation apparatus of claim 16, wherein the on-time of the DC pulse power and the on-time of the RF pulse power do not overlap each other.

18. The plasma generation apparatus of claim 16, wherein the on-time of the DC pulse power and the on-time of the RF pulse power overlap each other.

19. The plasma generation apparatus of claim 16, wherein the DC pulse power supplier is further configured to, when an electron density in a central area of the chamber is higher than an electron density in an area surrounding the central area, supply the DC pulse power having a positive voltage during an on-time of the DC pulse power.

20. The plasma generation apparatus of claim 16, wherein the DC pulse power supplier is further configured to, when electron density in a central area of the chamber is lower than an electron density in an area surrounding the central area, supply the DC pulse power having a negative voltage during an on-time of the DC pulse power.
